(19) United States
(12) Patent Application Publication
(10) Pub. No.: US 2016/0254180 A1
(43) Pub. Date: Sep. 1, 2016

(54) SELF ALIGNED RAISED FIN TIP END STI TO IMPROVE THE FIN END EPI QUALITY

(71) Applicant: GLOBALFOUNDRIES Inc., Grand Cayman (KY)

(72) Inventors: Bingwu LIU, Ballston Spa, NY (US); Hui ZANG, Guilderland, NY (US)

(73) Assignee: GLOBALFOUNDRIES INC., Grand Cayman (KY)

(21) Appl. No.: 14/633,341

(22) Filed: Feb. 27, 2015

(51) Int. Cl. H01L 21/762; H01L 21/8238; H01L 27/092; H01L 29/06; H01L 21/3105; H01L 21/308

(52) U.S. Cl. CPC H01L 21/76229; H01L 21/31051; H01L 21/308; H01L 27/0924; H01L 29/0649; H01L 21/823878; H01L 21/823821

(57) ABSTRACT

A method as set forth herein can include patterning using a first mask an isolation trench at a sidewall to sidewall isolation (SSI) region of a semiconductor structure having a substrate including fins and a main body section, filling the isolation trench at a SSI region with dielectric material, using a second mask to pattern an isolation trench at a single diffusion break (SDB) region, filling the isolation trench at the SDB region with dielectric material, and recessing dielectric material.

### TECHNICAL FIELD

The present invention relates to semiconductor structure and more particularly a semiconductor structure having an isolation region.

### BACKGROUND

In commercially available semiconductor structures, shallow trench isolation (STI) regions separate active device regions. Single diffusion (SDB) regions can separate active regions of the same polarity. Double diffusion break (DDB) regions can separate active regions of different polarity. A sidewall to sidewall isolation region can separate active regions that are adjacent each other in a direction transverse to a direction of a fin. Shallow trench isolation region can include a trench formed in a substrate. Shallow trench isolations can include dielectric, e.g., oxide formations. Poorly designed isolation regions can yield inconsistencies in device performance.

### BRIEF DESCRIPTION

A method as set forth herein can include patterning an isolation trench at a sidewall to sidewall isolation (SSI) region of a semiconductor structure having a substrate including fins and a main body section, filling the isolation trench at the SSI region with dielectric material, patterning an isolation trench at a single diffusion break (SDB) region, filling the isolation trench at the SDB region with dielectric material, and recessing dielectric material.

### BRIEF DESCRIPTION OF THE SEVERAL VIEWS OF THE DRAWINGS

One or more aspects as set forth herein are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 is a top view of a semiconductor structure in an intermediary stage of fabrication having a plurality of active FET regions and a plurality of isolation regions;

FIG. 2 is a flow diagram illustrating a fabrication method;

FIG. 3 is a cross sectional view of a semiconductor structure in an intermediary stage of fabrication after fin formation;

FIG. 4 is a cross sectional view of a semiconductor structure in an intermediary stage of fabrication after formation of a layer for use in patterning isolation trenches;

FIG. 5 is a cross sectional view of a semiconductor structure in an intermediary stage of fabrication after formation of an SSI region isolation trench;

FIG. 6 is a cross sectional view of a semiconductor structure in an intermediary stage of fabrication after formation of a DDB region isolation trench;

FIG. 7 is a cross sectional view of a semiconductor structure in an intermediary stage of fabrication after formation of a layer that can be formed of dielectric material;

FIG. 8 is a cross sectional view of a semiconductor structure in an intermediary stage of fabrication after planarization;

FIG. 9 is a cross sectional view of a semiconductor structure in an intermediary stage of fabrication after formation of a layer for use in patterning an isolation trench;

FIG. 10 is a cross sectional view of a semiconductor structure in an intermediary stage of fabrication after formation of an isolation trench;

FIG. 11 is a cross sectional view of a semiconductor structure in an intermediary stage of fabrication after pull back processing for enlarging of a trench;

FIG. 12 is a cross sectional view of a semiconductor structure in an intermediary stage of fabrication after filling of an isolation trench and planarization;

FIG. 13 is a cross sectional view of a semiconductor structure in an intermediary stage of fabrication after removal of a layer that can be a hardmask layer;

FIG. 14 is a cross sectional view of a semiconductor structure in an intermediary stage of fabrication after recessing of a dielectric material formation;

FIG. 15 is a cross sectional view of a semiconductor structure in an intermediary stage of fabrication after recessing of a dielectric material formation;

FIG. 16 is a cross sectional view of a semiconductor structure in an intermediary stage of fabrication after recessing of a dielectric material formation;

FIG. 17 is a cross sectional view of a semiconductor structure in an intermediary stage of fabrication;

FIG. 18 is a cross sectional view of a semiconductor structure in an intermediary stage of fabrication illustrating fabrication of a source/drain region;

FIG. 19 is a flow diagram illustrating a fabrication method;

FIG. 20 is a cross sectional view of a semiconductor structure in an intermediary stage of fabrication after formation of an isolation trench;

FIG. 21 is a cross sectional view of a semiconductor structure in an intermediary stage of fabrication after formation of a dielectric material formation;

FIG. 22 is a flow diagram illustrating a fabrication method.

### DETAILED DESCRIPTION

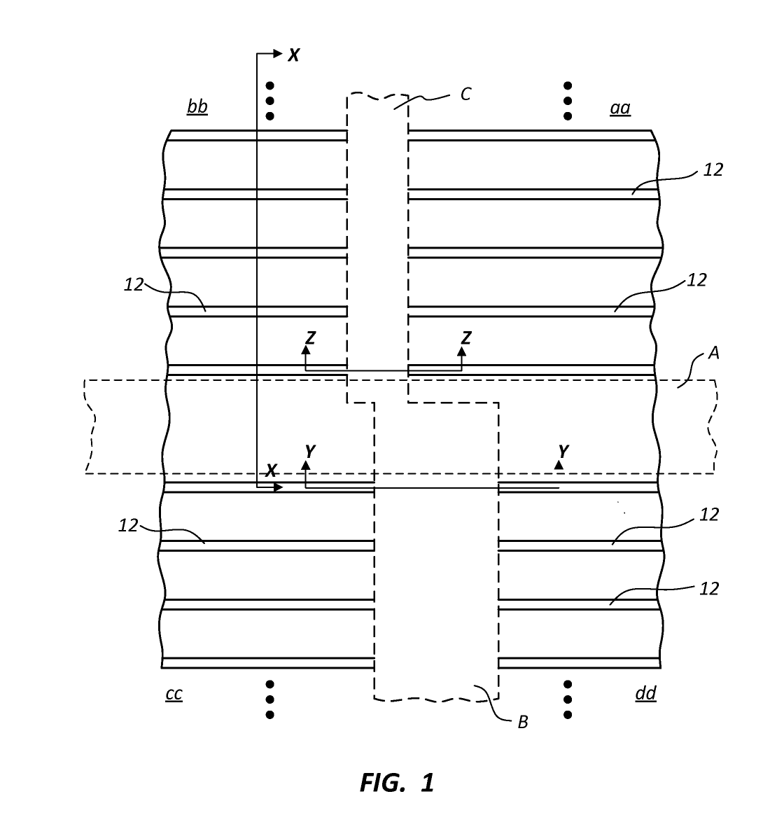

Referring to FIG. 1, FIG. 1 is a top view of a semiconductor structure 10 having various regions of FinFet active devices that are fabricated on Fins 12. Semiconductor structure 10 can have various active regions aa, bb, cc, and dd. Semiconductor structure 10 can have various isolation regions between active regions, e.g., referring to FIG. 1, region A can be a sidewall to sidewall isolation region, region B can be a double diffusion break region and region C can be a single diffusion break region.

Sidewall to sidewall isolation (SSI) region A can be provided to establish separation and isolation between active regions that are oriented in a direction in relation to one another that is transverse to a direction of fins 12. Sidewall to sidewall isolation (SSI) region A can extend in a direction parallel to a direction of fins 12.

Double diffusion break (DDB) region B can be provided to establish separation between active regions that have opposite polarity, e.g., active region dd and active region cc as shown in FIG. 1. In one embodiment active region dd can be a pFET region and active region cc can be an nFET region. In another embodiment active region dd can be an nFET region and active region cc can be a pFET region.

Regarding region C as shown in FIG. 1, region C can be a single diffusion break (SDB) region. Region C can be provided to establish separation between active regions of common polarity. In one example, active region aa can be an nFET region and active region bb can also be an nFET region. In another example, active region aa can be a pFET region and active region bb can be also be a pFET region.

In one embodiment, a method as set forth herein can include patterning an isolation trench at a sidewall to sidewall isolation (SSI) region of a semiconductor structure having a substrate including fins and a main body section, filling the isolation trench at the SSI region with dielectric material, patterning an isolation trench at a single diffusion break (SDB) region, filling the isolation trench at the SDB region with dielectric material, and recessing dielectric material.

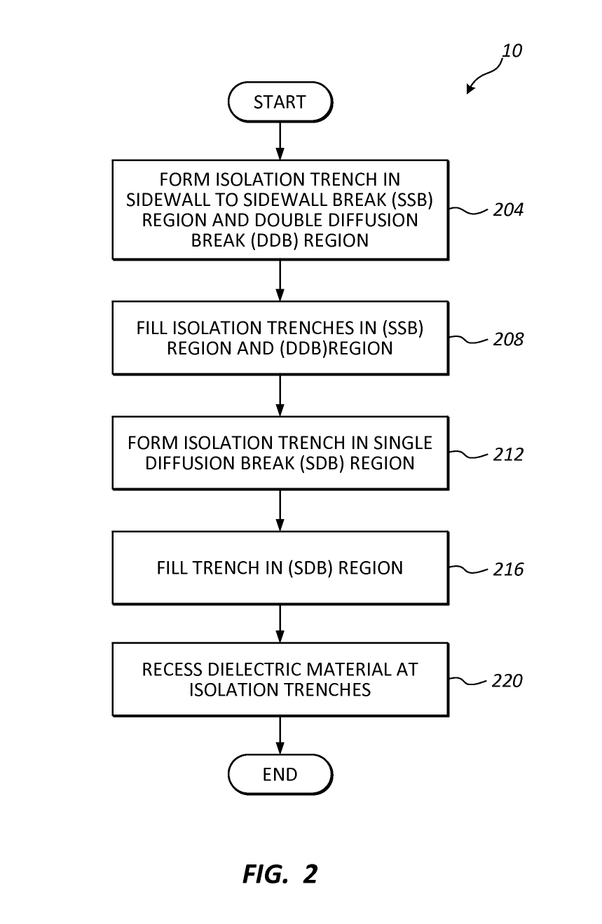

A method of fabrication of a semiconductor structure 10 in one embodiment is described with reference to the flow diagram of FIG. 2. At block 204, trenches can be formed in SSI region A and in DDB region B. At block 208, trenches in SSI region A and in a DDB region B can be filled. At block 212, there can be formed a trench in SDB region C. At block 216, a trench at SDB region C trench can be filled. At block 220, there can be performed recessing of trench dielectric material.

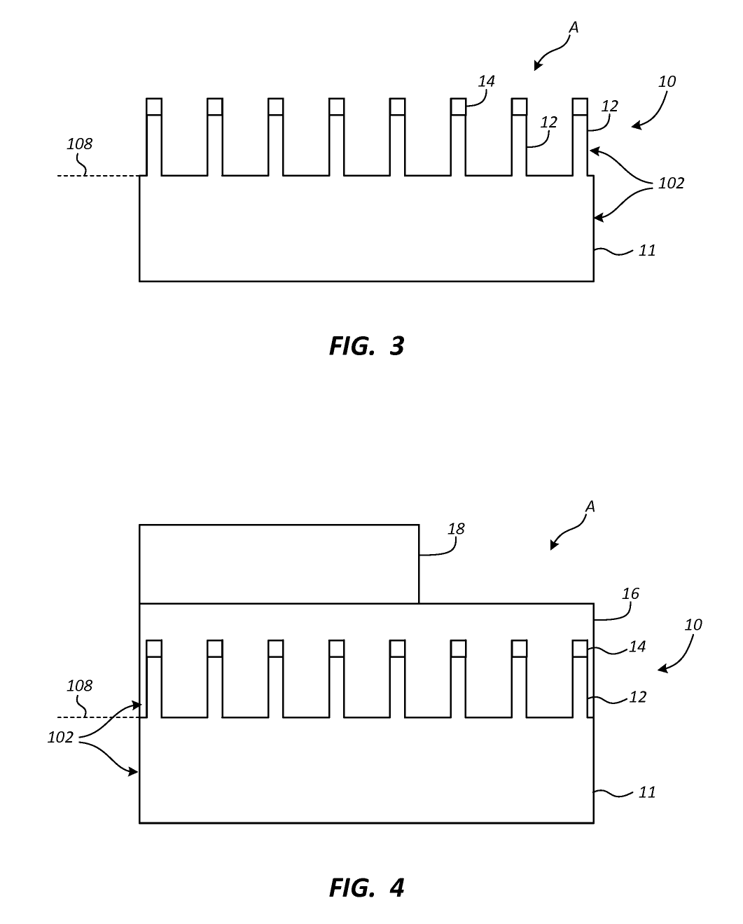

Further aspects of the noted processing blocks 204-220 are described with reference to reference to FIGS. 3-17.

Referring further to FIG. 2, at block 204 an isolation trench in SSI region A can be formed with a common etch process for forming a trench in DDB region B. At block 208, trenches defined at block 204 can be filled with a suitable dielectric material, e.g., an oxide. At block 212 there can be formed a trench on a SDB region C. At block 216, the trench formed at block 212 can be filled with a suitable dielectric material, e.g., an oxide. At block 220 there can be performed recessing of material filled in isolation trenches at block 208 and at block 216. The recessing can include simultaneously recessing material of layer 23 at each of trench 22, and trench 24, and layer 27 at trench 26.

Referring to FIG. 3, FIG. 3 is a cross sectional view taken along line x-x of FIG. 1 prior to fabrication of an isolated trench in region A. FIG. 3 is a fin widthwise cross sectional view illustrating aspects of fabrication of a trench within SSI region A. Referring to FIG. 3, semiconductor structure 10 in the cross section shown can include a substrate 102 having a fin 12 and a main body section 11. On a top of fin 12 there can be formed layer 14. Layer 14 can be an etch stop layer formed of, e.g., SiN.

Referring to FIG. 4, FIG. 4 illustrates semiconductor structure 10 as shown in FIG. 3 after formation of layer 16 and layer 18 in one embodiment. Layer 16 can be provided by dielectric material, e.g., an oxide and layer 18 can be formed of photoresist material. Layer 16 can be planarized to facilitate formation of layer 18 on layer 16. In an alternative embodiment, layer 16 can be provided by organic photoresist material.

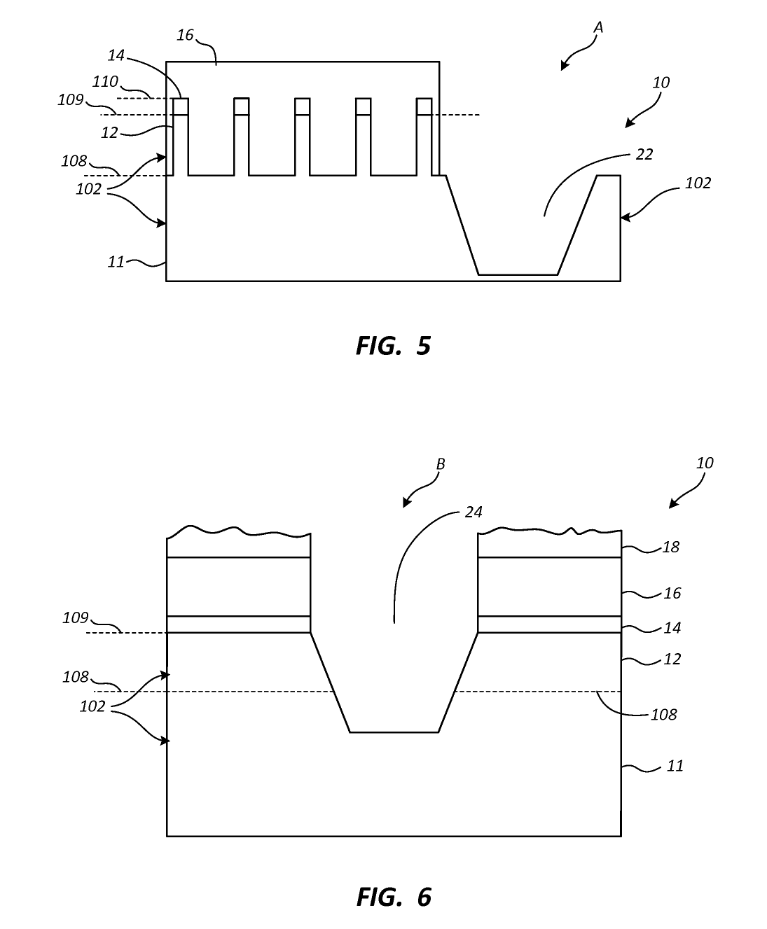

Referring to FIG. 5, FIG. 5 illustrates semiconductor structure 10 after removal of a section of material of layer 16, layer 14, fin 12 and main body section 11 to form isolation trench 22 in SSI region A. As shown in FIG. 5, trench 22 can extend below a top elevation 108 of main body section 11 of substrate 102.

With the formation of trench 22 at SSI region A of semiconductor structure 10 as shown in FIG. 5, there can be formed as shown in FIG. 6 trench 24 at DDB region B of semiconductor structure 10. Trench 22 can be formed simultaneously with trench 24. There is set forth herein in one embodiment a method wherein a patterning an SSI isolation trench 22 (FIG. 5) includes simultaneously patterning a double diffusion break (DDB) isolation trench 24 (FIG. 6).

FIG. 6 is a cross sectional view taken along line y-y of FIG. 1, i.e., rotated 90 degrees relative to cross sectional view of FIG. 5. It was described with references to FIG. 5 that layer 18 which can be formed of photoresist material, can be patterned for formation of trench 22 in SSI region A. In reference to FIG. 6, it is seen that layer 18 can also be patterned for formation of trench 24 in DDB region B simultaneously with the formation of trench 22 (FIG. 5). In one embodiment, layer 18 can be provided as a masking layer for commonly patterning in a common material formation stage each of trench 22 in SSI region A and of trench 24 in DDB region B. Referring to FIG. 6, isolation trench 24 can be formed according to the pattern of layer 18. Like trench 22, trench 24 can extend below a top elevation 108 of main body section 11 of substrate 102.

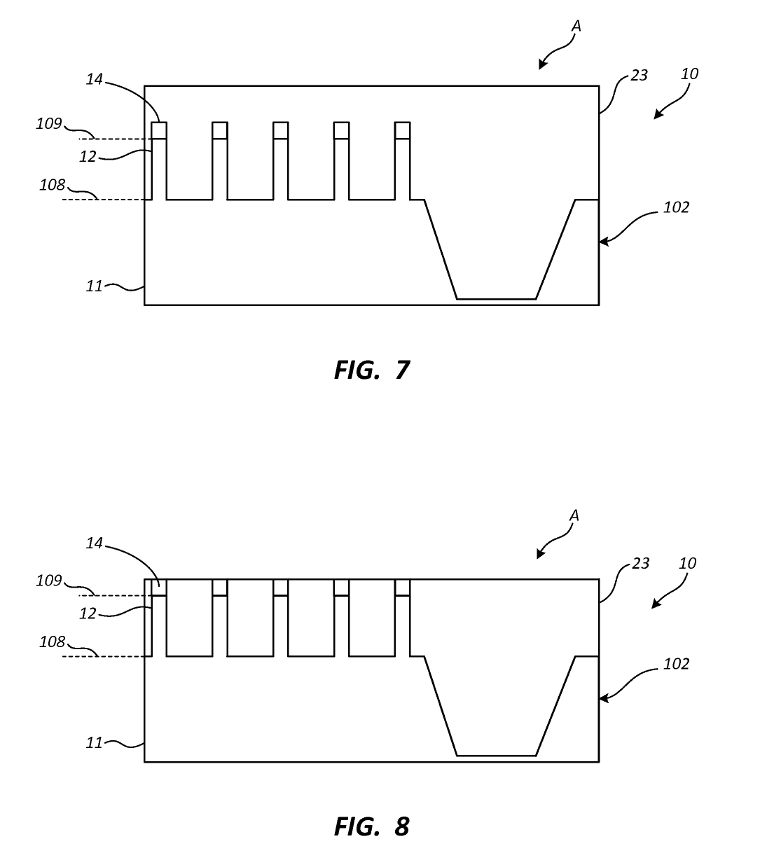

FIG. 7 illustrates semiconductor structure 10 as shown in FIG. 5 after formation of layer 23 within and over isolation trench 22. Layer 23 can be formed of a dielectric material, e.g., an oxide. When layer 23 is formed within and over isolation trench 22 as depicted in FIG. 7, layer 23 can simultaneously be formed within and over isolation trench 24 depicted in FIG. 6.

FIG. 8 is a cross sectional view illustrating the semiconductor structure 10 as shown in FIG. 7 after planarizing of semiconductor structure 10 to planarize layer 23 and layer 14. Planarizing can be performed using chemical mechanical planarization (CMP). With the planarization depicted in FIG. 8, layer 23 that fills trench 22 at SSI region A can be planarized to have a top elevation coplanar with layer 14. With the planarized depicted in FIG. 8, material of layer 23 that fills trench 24 at DDB region B (FIG. 6) can also be planarized to a top elevation of layer 14 so that a top elevation of layer 23 at DDB region B is coplanar with a top elevation of layer 14.

FIG. 9 is a cross sectional view of a semiconductor structure 10 as shown in FIG. 8 after formation of layer 32 on planarized layer 14 and layer 23.

With trench 22 of SSI region A and trench 24 of DDB region B previously formed using layer 18 (which can be a masking layer) and with trench 22 and trench 24 filled with material of layer 23, layer 32 can be formed as shown in FIG. 9 for use in patterning an isolation trench in SDB region C. In one embodiment, layer 32 can be a hardmask layer formed of hardmask material, e.g., silicon nitride (SiN).

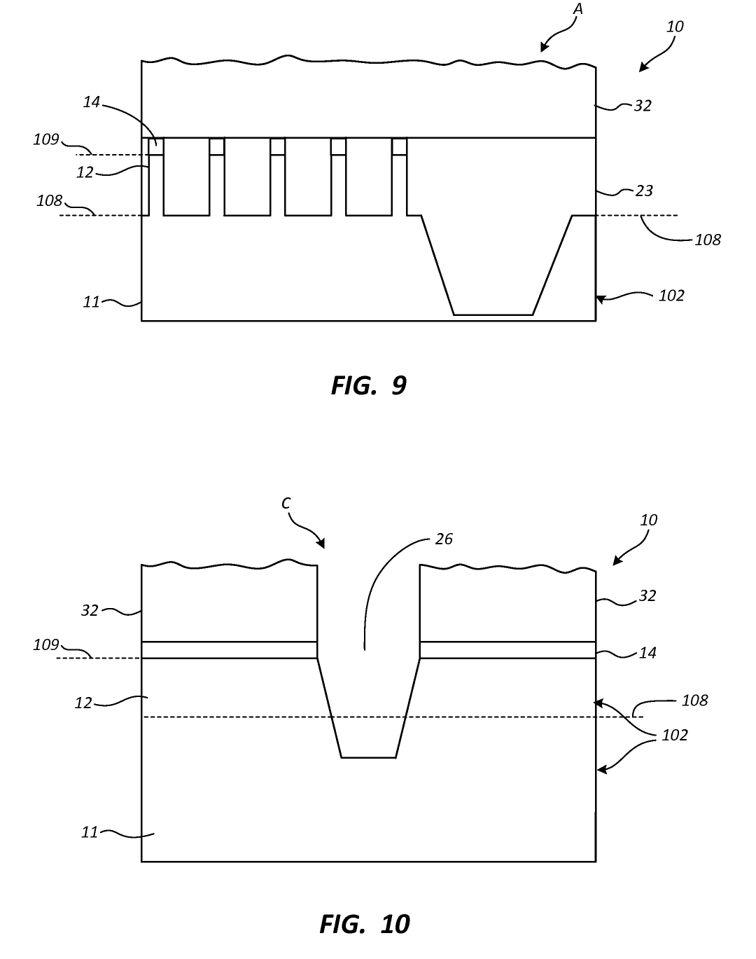

FIG. 10 is a cross sectional view taken along line z-z of FIG. 1 and illustrates formation of trench 26 within SDB region C according to the pattern of layer 32. Layer 32 can provide multiple functions. In one aspect, layer 32 can cover and protect SSI region A and SDB region B to serve as an etch stop layer when material is removed from semiconductor structure 10 for defining trench 26. In another aspect, layer 32 defines a depth of trench 26 to facilitate formation of trench 26 having an initial top elevation higher than a top elevation at trench 22 and trench 26. In other aspect, layer 32 can facilitate formation of a dielectric material formation which can be a single layer dielectric formation defined by layer 27 (to be described herein) having a top elevation higher than a top elevation 109 of substrate 102 and higher than a top elevation of formations at region A or region B.

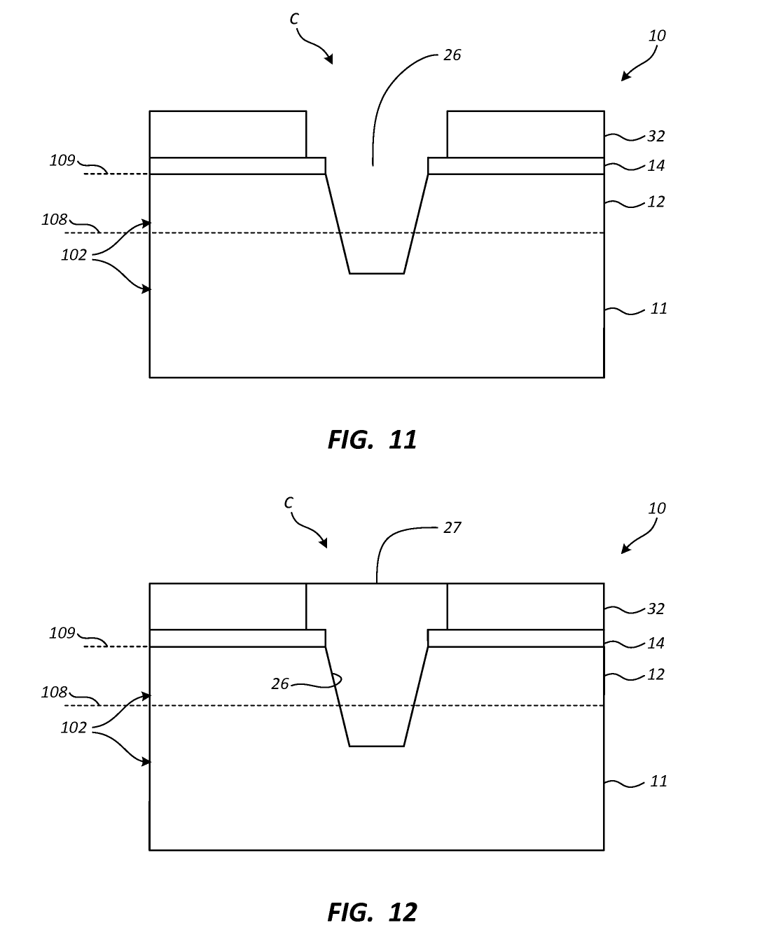

FIG. 11 illustrates the semiconductor structure 10 as shown in FIG. 10 after pull back processing for enlarging of trench 26. Referring to FIG. 11, layer 32 can be subject to etching. On being subject to etching, layer 32 can be reduced slightly in elevation and a width of trench 26 through layer 32 can be widened. Pull back processing of trench 26 depicted in FIG. 11 can result in shaping of trench to be T shaped as depicted in FIG. 11.

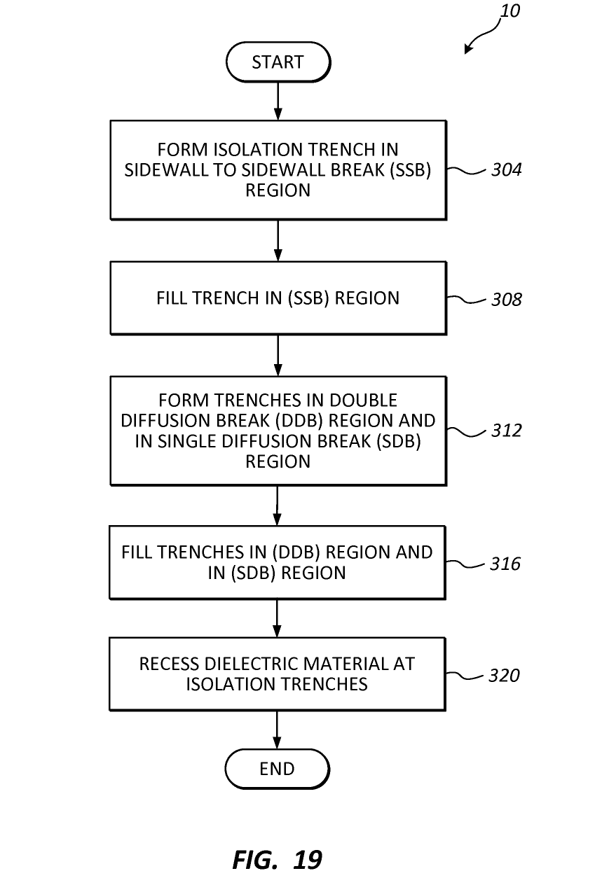

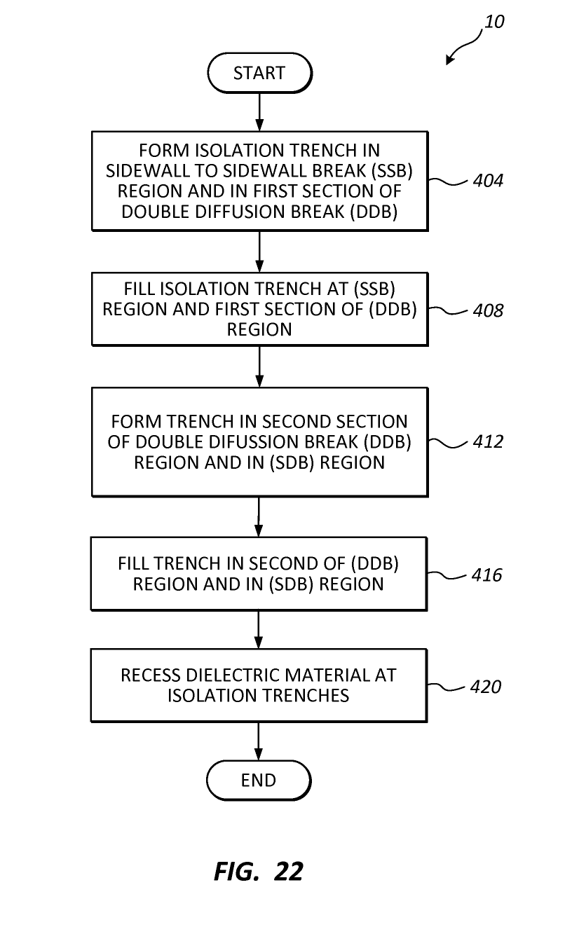

Referring to FIG. 12, FIG. 12 illustrates the semiconductor structure 10 as shown in FIG. 11 after formation of layer 27 in trench 26 and after planarization of semiconductor structure 10 using, e.g., CMP. Layer 32 and layer 27 can be planarized so that a top elevation of layer 32 and a top elevation of the dielectric material formation defined by layer 27 are coplanar. Layer 27 can be formed by using a single material deposition stage. The method set forth in reference to FIG. 2 (as well as the variations set forth in reference to FIGS. 19 and 22) can facilitate the formation of trench dielectric material formations of different height with economization of masks and with the dielectric material formations at each trench being formed with a single deposition stage. A dielectric material formation at each trench within the respective SSI region A, DDB region B and SDB region C can be a single layer dielectric material formation. Referring further to FIG. 12, layer 27 can be formed of a dielectric material, e.g., an oxide and as a result of the T shape of trench 26 as shown in FIG. 11 can define a formation that can be T shaped as shown in FIG. 12.

In reference to FIGS. 11 and 12 there is set forth herein an SDB isolation trench 26 that has an initial top elevation defined by layer 32 for patterning the SDB isolation trench 26, and wherein the filling the SDB isolation trench 26 at the SDB region C includes initially filling the dielectric material to a height occupied by the mask provided by layer 32 for patterning the SDB isolation trench 26.

There is also set forth herein in reference to FIGS. 11 and 12 a method wherein the initially filling the dielectric material of layer 27 to a height occupied by the mask provided by layer 32 for patterning the SDB isolation trench includes filling the dielectric material at least to a top elevation of layer 32 for patterning the SDB isolation trench 26.

There is also set forth herein with reference to FIGS. 11 and 12 a method wherein the initially filling the dielectric material of layer 27 to a height occupied by the mask provided by layer 32 for patterning the SDB isolation trench includes filling the dielectric material so that the dielectric material overfills a top elevation of layer 32 for patterning the SDB isolation trench 26.

There is also set forth herein with reference to FIGS. 11 and 12 a method wherein the initially filling the dielectric material of layer 27 to a height occupied by the mask provided by layer 32 for patterning the SDB isolation trench 26 includes filling the dielectric material so that the dielectric material overfills a top elevation of the mask provided by layer 32 for patterning the SDB isolation trench 26 and then planarizing the dielectric material.

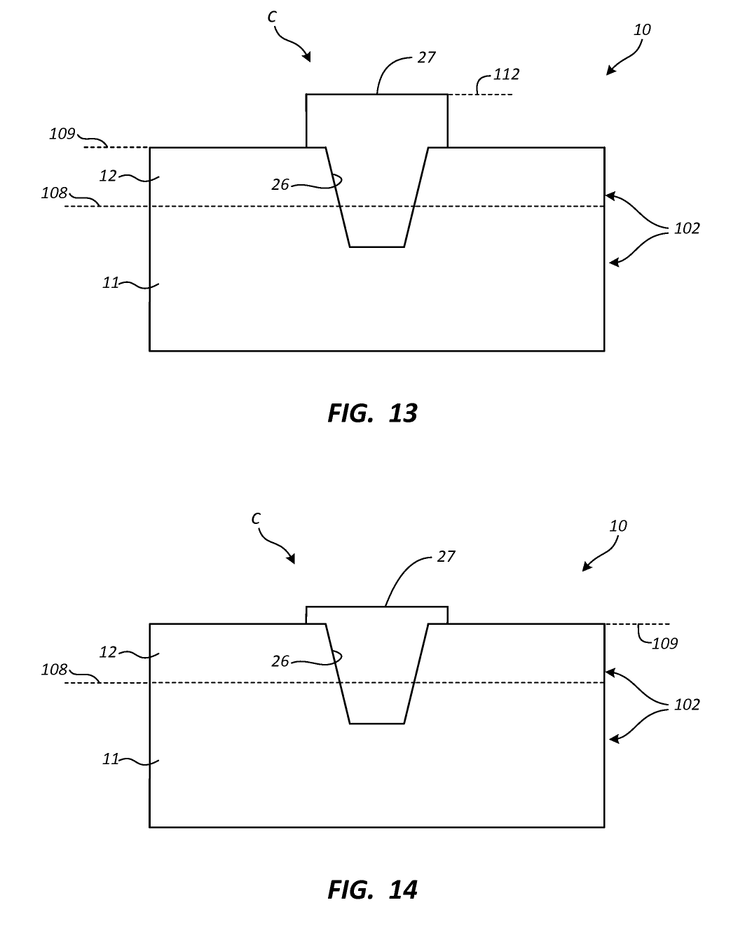

Referring to FIG. 13, FIG. 13 illustrates semiconductor structure 10 as shown in FIG. 12 after removal of layer 32 and layer 14. Removal of layer 32 and layer 14 can reduce an elevation of trench 26 from an original elevation.

Reference is now made to processing block 220 (FIG. 2) in which dielectric material within isolation regions at SSI region A, DDB region B, and SDB region C can be recessed. Prior to performance of recessing processing block 220 dielectric material of layer 23 at trenches 22 and 24 (at SSI region A and DDB region B) can be at elevation 110 (a top elevation of layer 14 as shown in FIGS. 5 and 8), and dielectric material of layer 27 at SDB region C can be at elevation 112 (FIG. 13) above elevation 110.

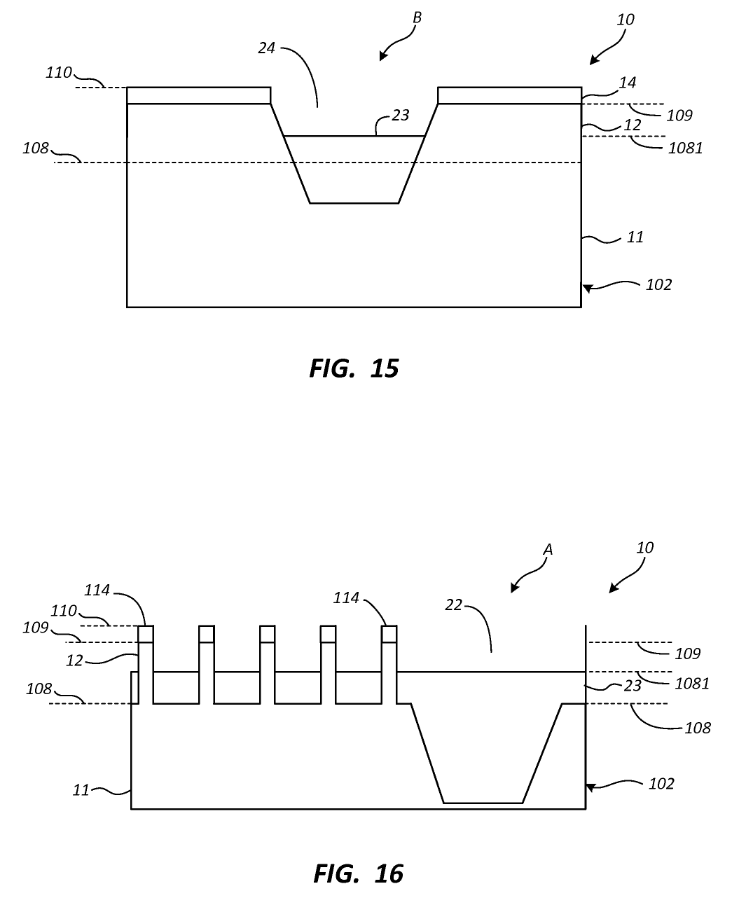

FIGS. 14, 15, and 16 illustrate various regions A, B, and C of semiconductor structure 10 after removal of a section of a dielectric material formation defined at trench 22, 24, and 26 at the various regions A, B, and C. Referring to FIG. 14, FIG. 14 illustrates removal of a section of material at layer 27 which can be dielectric, e.g., an oxide material at trench 26 within SDB region C. Referring to FIG. 15, FIG. 15 illustrates removal of a section of material of layer 23 at trench 24 within DDB region B. Referring to FIG. 16, FIG. 16 illustrates removal of a section of material as layer 23 at trench 22 within SSI region A.

It is seen that with the described processing including the removal of dielectric material at block 220 (FIG. 2) an elevation of a dielectric material formation defined by layer 23 can be reduced to an elevation 1081 below elevation 109 (a top elevation 109 of substrate 102) at SSI region A and below a top elevation 109 of substrate 102 at DDB region A (FIGS. 15 and 16). However, referring to FIG. 14, removal of dielectric material at block 220 (FIG. 2) can result in an elevation of the dielectric material formation defined by layer 27 within SDB region C as shown in FIG. 14 remaining above a top elevation 109 of substrate 102 that is filled by oxide formation 36.

Referring to FIGS. 3-16 it is seen that a shallow trench isolation architecture can be achieved in which DDB region B as shown in FIG. 15 and SSI region A as shown in FIG. 16 have dielectric material formation elevations below a top elevation 109 of their respective trenches 22 and 24 and in which SDB region C has a dielectric formation above a top elevation 109 of trench 26. With use of first and second masks, which can be provided by layer 18 (FIG. 4 and FIG. 6) used for formation of trench 22 and trench 24, (within SSI region A and DDB region B) and layer 32, respectively, for use in formation of trench 26 within SDB region C, advantages featured herein can be provided.

There is set forth herein a method wherein the filling the SSI isolation trench 22 (FIG. 16) includes forming a single layer dielectric material formation defined by layer 23 within an SSI isolation trench 22, and wherein the filling the SDB isolation trench 26 (FIG. 14) includes forming a single layer dielectric material formation defined by layer 27 within the SDB isolation trench 26. Single layer dielectric material formation herein can be deposited using a single deposition stage.

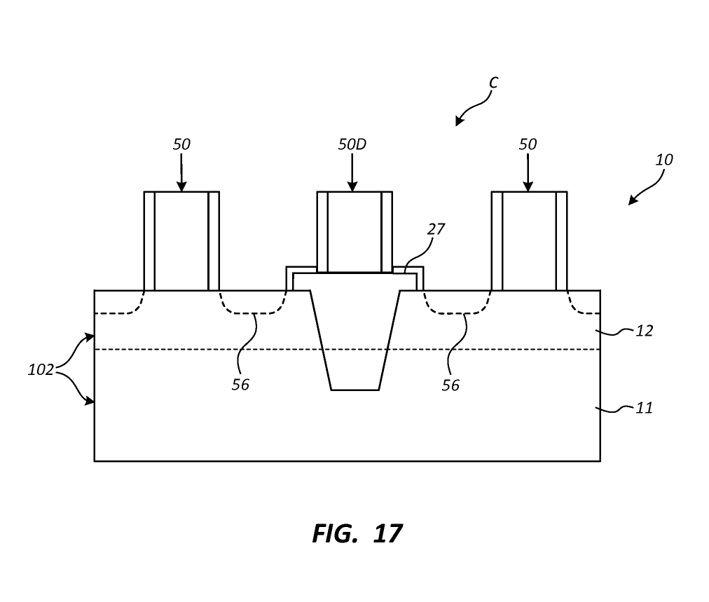

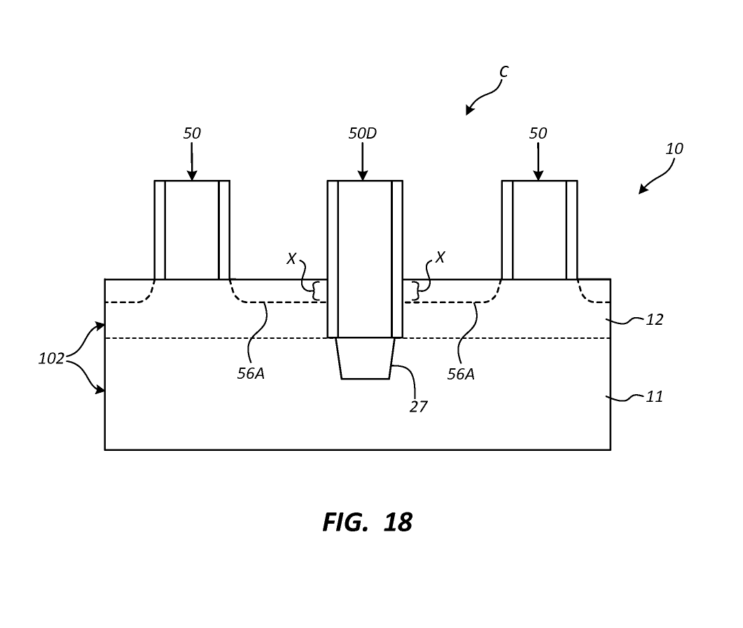

Referring to FIG. 17, FIG. 17 illustrates semiconductor structure 10 as shown in the cross sectional view of FIG. 14 after formation of gate 50, gate 50D, and gate 50 over a top elevation 109 of substrate 102 which is the top elevation of isolation trench 22 at SSI region A, isolation trench 24, and isolation trench 26. In the semiconductor structure 10 of FIG. 17, gates 50 can be active gates and gate 50D can be a dummy gate formed on layer 27 which can define a T-shaped dielectric material formation. For formation of source/drain regions associated to gates 50, substrate 102 adjacent each of the gates 50 can be recessed as shown by dotted lines 56 and then source/drain material can be epitaxially grown. It is seen that the T shape of the dielectric material formation defined by layer 27 encourages substantially symmetrically growth of epitaxially grown regions. By comparison, semiconductor structure 10 fabricated without a T shaped dielectric material formation defined by layer 27 is illustrated in FIG. 18. In the semiconductor structure 10 shown in FIG. 18, the dielectric material formation defined by layer 27 has a top elevation that does not extend above a top elevation 109 of substrate 102. Recessed sections of substrate 102 may be provided along dashed lines 56A rather than along dashed lines 56 as shown in FIG. 17. Accordingly, because epitaxially grown material cannot be grown on spacer dielectric material surfaces “X” exposed within recessed sections delimited by dashed lines 56A in the embodiment of FIG. 18, source/drain regions with a structure as shown in FIG. 18 may not be symmetrically grown. Asymmetrically grown epitaxial growth formations can lead to inconsistent or otherwise poor circuit operation.

Using the method as set forth in reference to FIGS. 2-17 there can be provided a semiconductor structure 10 having an STI architecture wherein trench dielectric material formations at regions A and B have top elevations below a top elevation 109 substrate 102, and wherein a trench dielectric material at region C has a T shape and a top elevation above a top elevation 109 of substrate 102.

Using the method set forth in reference to FIG. 19, there can be provided a semiconductor structure 10 having an STI architecture wherein trench dielectric material formations at SSI region A has a top elevation below a top elevation 109 of substrate 102, and wherein a trench dielectric material at regions B and C have a T shape and a top elevation above a top elevation 109 of substrate 102.

Referring to FIG. 19, at block 304 there can be formed an isolation trench at SSI region A. At block 308, there can be performed filling of the trench at region A with dielectric material. At block 312, there can be formed isolation trenches at DDB region B and at SDB region C.

At block 316, trenches at DDB region B and at SDB region C can be filled with dielectric material by formation of a layer of dielectric material within trenches of DDB region B and SDB region C. At block 320 dielectric material at isolation trenches of regions A, B and C can be recessed.

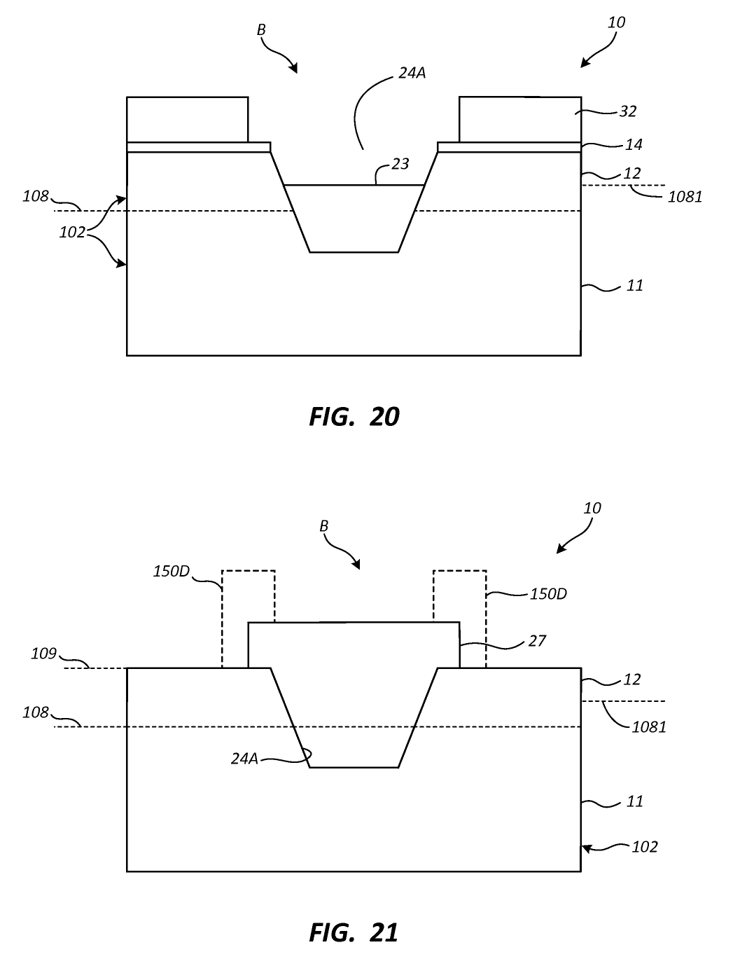

For performance of block 308 layer 18 as shown in FIGS. 4 and 6 (which can be a masking layer) can be modified so that SSI isolation trench 22 at region A can be patterned without patterning of any trench 24 at region B. For performance of block 316, layer 32 as shown in FIGS. 9 and 10 can be modified so that DDB isolation trench 24A at region B as shown in FIG. 20 can be patterned simultaneously with SDB isolation trench 26 at region C as shown in FIG. 11. There is set forth herein in one embodiment a method wherein the patterning an SDB isolation trench 26 includes simultaneously patterning a double diffusion break (DDB) isolation trench 24A. With use of the method set forth in FIG. 19, layer 23 can define a dielectric material formation as shown in FIG. 16 at SSI region A, layer 27 can define a T shaped dielectric material formation as shown in FIG. 21 at DDB region B and layer 27 can define a T shaped dielectric material formation as shown in FIGS. 13 and 14 at SDB region C. Referring to FIG. 21, the dielectric material formation defined by layer 27 at DDB region B can support dummy gates at locations indicated by dashed borders at 150D.

Using the method set forth in reference to FIG. 22, there can be provided a semiconductor structure 10 having an STI architecture wherein a trench dielectric material formation at SSI region A has a top elevation below a top elevation of substrate 102, and wherein a trench dielectric material at a first section of region B has a top elevation below a top elevation of 109 substrate 102, and wherein a dielectric material formation at a second section of region B and region C have a T shape and a top elevation above a top elevation 109 of substrate 102.

Referring to the flow diagram of FIG. 22, at block 404 there can be formed an isolation trench at SSI region A and at a first section of DDB region B. At block 408, there can be performed filling of the trench at SSI region A and the trench at the first section of the DDB region B with dielectric material by formation of a layer of dielectric material within trenches at SSI region A and a first section at DDB region B. At block 412, there can be formed isolation trenches at a second section of DDB region B and at SDB region C. At block 416, trenches at the second section of DDB region B and at SDB region C can be filled with dielectric material by formation of a layer of dielectric material within trenches as the second section of DDB region B and SDB region C. At block 420 dielectric material at isolation trenches of regions A, B and C can be recessed.

For performance of block 408 layer 18 as shown in FIGS. 4 and 6 (which can be a masking layer) can be modified so that SSI isolation trench 22 at region A can be patterned simultaneously with a patterning of DDB isolation trench 24 at a first section of DDB region B. For performance of block 416, layer 32 as shown in FIGS. 9 and 10 can be modified so that DDB isolation trench 24A as shown in FIG. 20 can be patterned in a second section of DDB isolation region B simultaneously with SDB isolation trench 26 at region C as shown in FIG. 11. There is set forth herein a method wherein the patterning an SSI isolation trench 22 includes simultaneously patterning a double diffusion break (DDB) trench 24, and wherein the patterning an SDB isolation trench 26 includes simultaneously patterning a double diffusion break (DDB) trench 24A. With use of the method set forth in FIG. 22, the dielectric material formation defined by layer 23 as shown in FIG. 16 can be formed at SSI region A, the dielectric material formation defined by layer 23 as shown in FIG. 15 can be formed at a first section of region B, the dielectric material formation defined by layer 27 as shown in FIG. 21 can be formed at a second section of region B and the dielectric material formation defined by layer 27 as shown in FIGS. 13 and 14 can be formed at SDB region C.

Each of the deposited layers as set forth herein, e.g., layer 14, layer 16, layer 18, layer 23, layer 32, layer 27, layer 142, layer 152, layer 130, layer 116, layer 162, layer 166, layer 176, layer 178 and/or layer 154 can be deposited using any of a variety of deposition processes, including, for example, physical vapor deposition (PVD), atomic layer deposition (ALD), chemical vapor deposition (CVD), sputtering, or other known processes, depending on the material composition of the layer.

In one example, a protective mask layer as set forth herein, e.g., a mask layers for patterning layer 142, layer 152, layer 130, layer 116, layer 162, layer 166, layer 176, layer 178 and/or layer 154 as set forth herein may include a material such as, for example, silicon nitride, silicon oxide, or silicon oxynitride, and may be deposited using conventional deposition processes, such as, for example, CVD or plasma-enhanced CVD (PECVD). In other examples, other mask materials may be used depending upon the materials used in semiconductor structure. For instance, a protective mask layer may be or include an organic material. For instance, flowable oxide such as, for example, a hydrogen silsesquioxane polymer, or a carbon-free silsesquioxane polymer, may be deposited by flowable chemical vapor deposition (F-CVD). In another example, a protective mask layer may be or include an organic polymer, for example, polyacrylate resin, epoxy resin, phenol resin, polyamide resin, polyimide resin, unsaturated polyester resin, polyphenylene ether resin, polyphenylenesulfide resin or benzocyclobutene (BCB).

Removing material of a layer as set forth herein, e.g., layer 142, layer 152, layer 130, layer 116, layer 162, layer 166, layer 176, layer 178 and/or layer 154 can be achieved by any suitable etching process, such as dry or wet etching processing. In one example, isotropic dry etching may be used by, for example, ion beam etching, plasma etching or isotropic RIE. In another example, isotropic wet etching may also be performed using etching solutions selective to the material subject to removal.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method comprising:
patterning a sidewall to sidewall isolation (SSI) trench at an SSI region of a semiconductor structure having a substrate including fins and a main body section;
filling the SSI isolation trench with dielectric material;
patterning a single diffusion break (SDB) isolation trench at an SDB region; and
filling the SDB isolation trench with dielectric material.

2. The method of claim 1, wherein the SDB isolation trench has an initial height defined by a mask for patterning the SDB isolation trench, and wherein the filling the SDB isolation trench at the SDB region includes initially filling the dielectric material to a height occupied by the mask for patterning the SDB isolation trench.

3. The method of claim 2, wherein the initially filling the dielectric material to a height occupied by the mask for patterning the SDB isolation trench includes filling the dielectric material at least to a top elevation of the mask for patterning the SDB isolation trench.

4. The method of claim 2, wherein the initially filling the dielectric material to a height occupied by the mask for patterning the SDB isolation trench includes filling the dielectric material so that the dielectric material overfills a top elevation of the mask for patterning the SDB isolation trench.

5. The method of claim 2, wherein the initially filling the dielectric material to a height occupied by the mask for patterning the SDB isolation trench includes filling the dielectric material so that the dielectric material overfills a top elevation of the mask for patterning the SDB isolation trench and then planarizing the dielectric material.

6. The method of claim 1, wherein the filling the SDB isolation trench includes forming a single layer dielectric material formation within the SDB isolation trench.

7. The method of claim 1, wherein the filling the SSI isolation trench includes forming a single layer dielectric material formation within the SSI isolation trench, and wherein the filling the SDB isolation trench includes forming a single layer dielectric material formation within the SDB isolation trench.

8. The method of claim 1, wherein the patterning an SSI isolation trench includes simultaneously patterning a double diffusion break (DDB) isolation trench.

9. The method of claim 1, wherein the patterning an SDB isolation trench includes simultaneously patterning a double diffusion break (DDB) isolation trench.

10. The method of claim 1, wherein the patterning an SSI isolation trench includes simultaneously patterning a double diffusion break (DDB) trench, and wherein the patterning an SDB isolation trench includes simultaneously patterning a double diffusion break (DDB) trench.

11. The method of claim 1, wherein the filling the SSI isolation trench includes forming a single layer dielectric material formation within the SSI isolation trench, and wherein the filling the SDB isolation trench includes forming a single layer dielectric material formation within the SDB isolation trench, and wherein the method further includes forming a single layer dielectric material formation within a DDB isolation trench.

12. The method of claim 1, wherein the method includes recessing dielectric material of the SSI isolation trench and the SDB isolation trench so that a dielectric material formation at the SSI region has a top elevation lower than a top elevation of the substrate and further so that a dielectric material formation at the SDB region has an elevation higher than a top elevation of the substrate.

13. The method of claim 1, wherein the patterning the SSI region includes using a mask and wherein the method includes patterning a double diffusion break (DDB) isolation trench at a DDB region using the mask.

14. The method of claim 1, wherein the patterning the SDB trench includes using mask and wherein the method includes patterning a double diffusion break (DDB) isolation trench at a DDB region using the mask.

15. The method of claim 1, wherein the patterning the SSI trench includes using a first mask, wherein the method includes patterning a double diffusion break (DDB) isolation trench at a first section of a DDB region, wherein the patterning a DDB region includes using a second mask, and wherein the method includes patterning a DDB isolation trench at a second section of a DDB region using the second mask.

16. The method of 1, wherein the method includes processing the isolation trench at a SDB region so that the isolation trench at a SDB region is T shaped.

17. A semiconductor structure comprising:
a substrate having a main body section and a plurality of fins;
a sidewall to sidewall isolation (SSI) region defined between fins of the plurality of fins, the SSI region having an SSI isolation trench; and
a single diffusion break (SDI) region defined between active FET regions of common polarity formed on the substrate, the SDB region having an SDB isolation trench;
a dielectric material formation at the SSI region having a top elevation lower than a top elevation of the substrate;
a dielectric material formation at the SDB region having a top elevation higher than a top elevation of the substrate.

18. The semiconductor structure of claim 17, wherein the dielectric material formation at the SDB region has a T shape.

19. The semiconductor structure of claim 17, comprising a double diffusion break (DDB) region between active FET regions of opposite polarity formed on the substrate, and a dielectric material formation at the DDB region, wherein the dielectric material formation at the DDB region has a top elevation lower than a top elevation of the substrate.

20. The semiconductor structure of claim 17, wherein the dielectric material formation at a certain section of the DDB region has a T shape and a top elevation higher than a top elevation of the substrate.
